(19) United States
(12) Patent Application Publication
(10) Pub. No.: US 2025/0035715 A1
(43) Pub. Date: Jan. 30, 2025

(54) DISCONNECTION DETECTION METHOD AND DISCONNECTION DETECTION DEVICE

(71) Applicant: Proterial, Ltd., Tokyo (JP)

(72) Inventors: Takahiro SUGIYAMA, Tokyo (JP); Izumi FUKASAKU, Tokyo (JP); Kei NISHIMURA, Tokyo (JP); Hideki NONEN, Tokyo (JP)

(21) Appl. No.: 18/739,987

(22) Filed: Jun. 11, 2024

(30) Foreign Application Priority Data
Jul. 14, 2023 (JP) 2023-116226

(51) Int. Cl. G01R 31/58; B25J 19/00

(52) U.S. Cl. CPC G01R 31/58; B25J 19/0066

(57) ABSTRACT

A disconnection detection method for detecting disconnection of a plurality of strands constituting a conductor of a cable wired in a device that is caused by motion of the device includes a data acquisition step of acquiring motion information data, which is data showing changes over time in information about motion of the device, and resistance value data, which is data of a resistance value of the conductor that changes in time series due to the motion of the device, an analysis step of analyzing the resistance value data based on the motion information data acquired in the data acquisition step and obtaining an index value to detect strand disconnection, and a disconnection detection step of detecting the strand disconnection based on the index value obtained in the analysis step.

### CROSS-REFERENCE TO RELATED APPLICATIONS

The present patent application claims the priority of Japanese patent application No. 2023-116226 filed on Jul. 14, 2023, the entire contents of which are incorporated herein by reference.

### TECHNICAL FIELD

The present invention relates to a disconnection detection method and a disconnection detection device.

### BACKGROUND OF THE INVENTION

In cables wired in moving parts of devices such as industrial robots, disconnection (i.e., wire breakage) of strands constituting the conductor proceeds gradually by being subjected to repeated motion, such as bending or twisting, of the moving parts, eventually leading to conductor disconnection. Therefore, it is desirable to detect strand disconnection and replace the cable before reaching disconnection of the entire conductor.

When disconnection occurs in a small number of strands in a conductor, the change in the resistance value of the conductor is very small and it is difficult to distinguish it from noise at the time of detection. Therefore, conventionally, it is judged that the conductor is close to complete disconnection when the resistance value of the conductor increases by several tens of percent from its initial value, and disconnection of the conductor is often determined at this point. However, in this case, there is not enough time (or the number of times of motion) between detection of disconnection and the complete disconnection of the entire conductor, and disconnection of the entire conductor may occur before replacement of the cable, causing the device such as industrial robot to stop operating.

Patent Literature 1 proposes a method in which a resistance value of a conductor when the cable is moved (bent, twisted, etc.) at a fixed cycle is measured and strand disconnection is detected based on the result of frequency analysis on the fluctuation of the resistance value. Because of the high sensitivity of this method, it is possible to detect the strand disconnection even at the stage where, e.g., disconnection occurred in one strand.

Citation List Patent Literature 1: JP 2021-162570A

### SUMMARY OF THE INVENTION

Users who use devices such as industrial robots (device users) or manufacturers who produce such devices (device manufacturers) perform maintenance on the devices such as industrial robots. In device maintenance, industrial robots, etc., which are devices to be managed, are inspected after stopping its operation. However, to reduce the likelihood of occurrence of sudden shutdowns due to failures during when devices are in actual operation, it is desirable to be able to perform maintenance while the devices are in actual operation. It is particularly desirable that whether disconnection of strands of cables mounted on devices such as industrial robots has occurred can be detected during when the devices is in actual operation.

Therefore, it is an object of the invention to provide a disconnection detection method and a disconnection detection device that are capable of detecting the strand disconnection even when a device on which a cable is mounted is in actual operation.

To solve the problems described above, the invention provides a disconnection detection method for detecting disconnection of a plurality of strands constituting a conductor of a cable wired in a device that is caused by motion of the device, the method comprising:
a data acquisition step of acquiring motion information data, which is data showing changes over time in information about motion of the device, and resistance value data, which is data of a resistance value of the conductor that changes in time series due to the motion of the device;
an analysis step of analyzing the resistance value data based on the motion information data acquired in the data acquisition step and obtaining an index value to detect strand disconnection; and
a disconnection detection step of detecting the strand disconnection based on the index value obtained in the analysis step.

To solve the problems described above, the invention also provides a disconnection detection device that detects disconnection of a plurality of strands constituting a conductor of a cable wired in a device that is caused by motion of the device, the disconnection detection device comprising:
a data acquisition processing unit that acquires motion information data, which is data showing changes over time in information about motion of the device, and resistance value data, which is data of a resistance value of the conductor that changes in time series due to the motion of the device;
an analytical processing unit that analyzes the resistance value data based on the motion information data acquired by the data acquisition processing unit and obtains an index value to detect strand disconnection; and
a disconnection detection processing unit that detects the strand disconnection based on the index value obtained by the analytical processing unit.

To solve the problems described above, the invention also provides a disconnection detection device that detects disconnection of a plurality of strands constituting a conductor of a cable wired in a device that is caused by motion of the device, the disconnection detection device comprising:
a data acquisition processing unit that acquires resistance value data which is data of a resistance value of the conductor that changes in time series due to the motion of the device;
an analytical processing unit that generates motion information data, which is data showing changes over time in information about motion of the device, from the resistance value data, analyzes the resistance value data based on the motion information data and obtains an index value to detect strand disconnection; and
a disconnection detection processing unit that detects the strand disconnection based on the index value obtained by the analytical processing unit.

### Advantageous Effects of the Invention

According to the invention, it is possible to provide a disconnection detection method and a disconnection detection device that are capable of detecting strand disconnection even when a device on which a cable is mounted is in actual operation.

### BRIEF DESCRIPTION OF DRAWINGS

FIG. 1 is a schematic configuration diagram illustrating a disconnection detection device in an embodiment of the present invention.

FIGS. 2A to 2C are explanatory diagrams illustrating analytical processing.

FIG. 3A is a flowchart showing a disconnection detection method in the embodiment of the invention.

FIG. 3B is a flowchart showing the analytical processing.

FIGS. 4A to 4C are diagrams illustrating examples of changes in index values I.

FIG. 5 is a diagram illustrating an example of changes in index values Ix.

FIG. 6 is a flowchart showing the analytical processing in another embodiment of the invention.

FIG. 7 is an explanatory diagram illustrating disconnection detection for plural moving parts.

FIG. 8 is a flowchart showing the analytical processing in a modification of the invention.

### DETAILED DESCRIPTION OF THE INVENTION

### Embodiments

Embodiments of the invention will be described below in conjunction with the appended drawings.

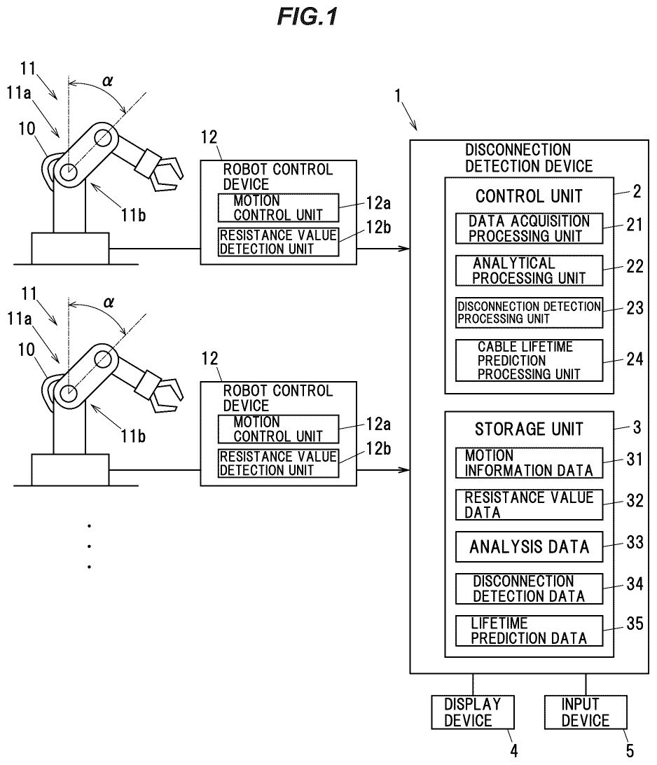

FIG. 1 is a schematic configuration diagram illustrating a disconnection detection device 1 in the present embodiment. The disconnection detection device 1 is a device that detects disconnection of strands consisting of metal wires and constituting a conductor of a cable 10 wired in a device (a management target device) 11 managed by a device user or a device manufacturer, which is caused by motion such as bending or twisting applied due to motion based on the actual operation of the device 11. The device 11 has a moving part 11b, and the cable 10 is wired through the moving part 11b. By operating the moving part 11b of the device 11, bending or twisting, etc. is repeatedly applied to the cable 10. FIG. 1 shows a case where the device 11 in which the cable 10 is wired is an industrial robot 11a. The conductor of the cable 10 to be subjected to disconnection detection is constructed from a stranded conductor formed by twisting plural strands together.

Hereinafter, the term “strand disconnection” means disconnection of each of plural strands constituting the conductor of the cable 10. In addition, the term “conductor disconnection progress state” means a disconnection rate indicating how many of the plural strands constituting the conductor are disconnected (i.e., broken) due to motion such as bending or twisting, etc. repeatedly applied to the cable 10, i.e., the number of disconnected strands out of the total number of the plural strands constituting the conductor. The conductor disconnection progress state can be expressed by the ratio (%) of the number of disconnected strands to the total number of plural strands constituting the conductor. For example, the progress state of disconnection of strands constituting the conductor or disconnection of the conductor when the disconnection rate is 100% indicates the state in which all the plural strands constituting the conductor are disconnected. That is, it can be said that the conductor disconnection progress state is the disconnection progress state of the cable 10.

In addition, the term “conductor disconnection” means that the disconnection rate of the conductor has reached a preset rate where it is determined that the conductor is disconnected. For example, the point at which the rate of increase in the resistance value of the conductor constituting the cable 10 (the rate of increase in the resistance value of the conductor with respect to its initial resistance value) becomes not less than 20% is set as a state of the conductor determined to be disconnected, and the disconnection rate of the conductor (=the conductor disconnection progress state) at this point is, e.g., not less than 80%. The conductor disconnection indicates the stage where it is determined that the cable 10 has reached the end of its life (=cable lifetime), and it serves as an indicator to prompt replacement of the cable 10.

A robot control device 12 to control the industrial robot 11a is connected to the industrial robot 11a. A motion control unit 12a to control motion of the industrial robot 11a (motion of the moving part 11b) is mounted on the robot control device 12. A motion program (not shown) in which the sequence of motion, angle and speed of motion, etc. of the moving part 11b are set in advance is stored in the robot control device 12, and the motion control unit 12a operates the industrial robot 11a according to the motion program.

A resistance value detection unit 12b to detect the resistance value of the conductor of the cable 10 is also mounted on the robot control device 12. The detection method used in the resistance value detection unit 12b is not particularly limited. That is, the resistance value detection unit 12b may have any configuration as long as it can detect the resistance value of the conductor, and it may be configured to obtain the resistance value based on, e.g., a ratio of voltage applied to the conductor to a current flowing through the conductor. In this regard, the resistance value detection unit 12b does not need to be mounted on the robot control device 12, and may be mounted on, e.g., a dedicated unit (module) for resistance detection arranged between the industrial robot 11a and the disconnection detection device 1, or may be mounted on the disconnection detection device 1 or the industrial robot 11a. Since the resistance value detection unit 12b is mounted on the unit (module), the resistance value of the conductor of the cable 10 can be detected by connecting the industrial robot 11a and the resistance value detection unit 12b and the robot control device 12 to each other, without complicated modifications of the respective structures of the industrial robot 11a and the robot control device 12. The resistance detected by the resistance value detection unit 12b is transmitted to the disconnection detection device 1 and stored as resistance value data 32 in a storage unit 3 of the disconnection detection device 1.

Disconnection detection device 1

The disconnection detection device 1 has a control unit 2 and the storage unit 3. The disconnection detection device 1 is also connected to a display device 4, and is configured to be able to display motion information data 31 and the resistance value data 32 (described later), or various information such as results of disconnection detection, on the display device 4. An input device 5 such as a keyboard is also provided on the disconnection detection device 1 so that various settings and manipulation of the display contents on the display device 4 can be performed by input from the input device 5. The display device 4 may be configured as a touch panel display so that the display device 4 also serves as the input device 5. Furthermore, the connection of the display device 4 and the input device 5 to the disconnection detection device 1 does not need to be by wire and may be wireless connection. In this case, the display device 4 or the input device 5 may be, e.g., a smartphone or a tablet.

The control unit 2 has a data acquisition processing unit 21, an analytical processing unit 22, disconnection detection processing unit 23, and a cable lifetime prediction processing unit 24. The data acquisition processing unit 21, the analytical processing unit 22 and the disconnection detection processing unit 23 are realized by appropriately combining an arithmetic element such as a CPU, a memory such as RAM or ROM, software, interface, and a storage device, etc.

Data acquisition processing unit 21

The data acquisition processing unit 21 performs data acquisition processing to acquire the motion information data 31, which is data showing changes over time in information about motion of the device 11, and the resistance value data 32, which is data of the resistance value of the conductor that changes in time series due to the motion of the device 11. The motion of the device 11 is, e.g., the motion of the moving part 11b at the time the device 11 is in actual operation. The data acquisition processing corresponds to the data acquisition step of the invention. The data acquisition processing unit 21 acquires the motion information data 31 and the resistance value data 32 during when the device 11 is in actual operation.

In the present embodiment, angle information of the moving part 11b is used as the information about the motion of the moving part 11b. That is, in the present embodiment, the motion information data 31 is data showing changes over time in an angle a of the moving part 11b. The angle information of the moving part 11b may be acquired from the motion program stored in the robot control device 12, or may be obtained from a sensor attached to the moving part 11b of the industrial robot 11a or obtained by detecting a drive current of a motor that drives the moving part 11b. The resistance value data 32 may be received from the resistance value detection unit 12b of the robot control device 12.

Analytical processing unit 22

The analytical processing unit 22 performs analytical processing to analyze the resistance value data 32 based on the motion information data 31 acquired by the data acquisition processing unit 21. The analytical processing corresponds to the analysis step of the invention. In the present embodiment, for each state of motion (in this example, the angle α), the analytical processing unit 22 calculates an average value of the resistance value over a predetermined period of time when the motion is in that state.

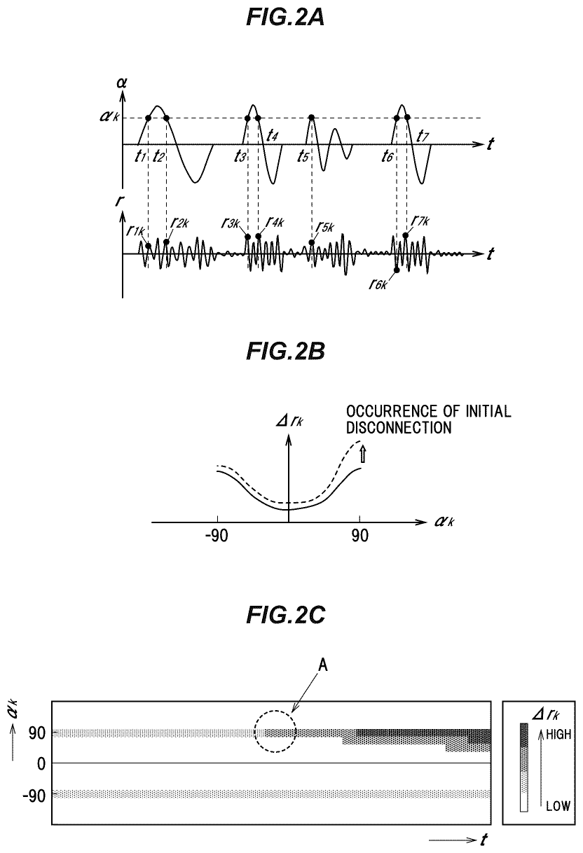

FIGS. 2A to 2C are explanatory diagrams illustrating analytical processing. As shown in FIG. 2A, the moving part 11b moves intermittently at various speeds during when the industrial robot 11a is in operation. In the analytical processing, analysis is performed on only the data during a predetermined period of time (e.g., 30 minutes) among the motion information data 31 and the resistance value data 32. The period to be analyzed can be appropriately set in consideration of the motion cycle of the moving part 11b. Since the time at which the angle α of the moving part 11b becomes an arbitrary angle αₖ appears plural times, the analytical processing unit 22 extracts resistance values rₙₖ (n is an integer of not less than 1) when the angle α of the moving part 11b becomes the arbitrary angle αₖ. In the example shown in FIG. 2A, the angle αₖ is reached at times t₁, t₂, . . . , t₇, hence, resistance values r₁ₖ, r₂ₖ, . . . , r₇ₖ corresponding to times t₁, t₂, . . . , t₇ are extracted. Then, the analytical processing unit 22 obtains an average value rₖ of the extracted resistance values using the following equation (1).

$${r}_{k} = \frac{{r}_{1 k} + {r}_{2 k} + {r}_{3 k} + {r}_{4 k} + {r}_{5 k} … + {r}_{nk}}{n} \qquad ( 1 )$$

In the present embodiment, an index value Δrₖ is further obtained by subtracting the average value at the angle αₖ=0 from the average value rₖ and normalizing the value. That is, the average value r₀ at the angle αₖ=0 is obtained using the following equation (2), and the index value Δrₖ is obtained using the following equation (3).

$${r}_{0} = \frac{{r}_{10} + {r}_{20} + {r}_{30} + {r}_{40} + {r}_{50} … + {r}_{m 0}}{n} \qquad ( 2 )$$

$$Δ {r}_{k} = {r}_{k} - {r}_{0} \qquad ( 3 )$$

By obtaining the index value Δrₖ for each angle in the same manner, it is possible to obtain a relationship of the index value Δrₖ to the angle αₖ as shown in FIG. 2B. Even in a state where there is no disconnection, the resistance value of the conductor changes due to the effect of strain applied by the motion of the moving part 11b. In the example shown in the drawing, the resistance value of the conductor becomes large due to the effect of strain when the angle αₖ is ±90 degrees. When disconnection occurs in the strands constituting the conductor, the distance between the strands changes at the location of disconnection according to the motion of the moving part 11b, and the resistance value of the conductor fluctuates accordingly. For example, when the point at which disconnection of the first of the plural strands constituting the conductor occurs is defined as initial disconnection, the resistance value of the conductor becomes large due to occurrence of the initial disconnection. As a result, when strand disconnection occurs, the resistance value (the index value Δrₖ) becomes large at a predetermined angle αₖ. Such a change in the resistance value is very small and is usually buried in noise components and difficult to observe. However, by obtaining the average value rₖ of the resistance value over some long period of time and further defining a difference from the average r₀ of resistance value at αₖ=0 as the index value Δrₖ, changes in the resistance value of the conductor due to strand disconnection can be extracted based on changes in the index value Δrₖ. The analytical processing unit 22 stores the calculation result of the index value Δrₖ for each angle αₖ as analysis data 33 in the storage unit 3.

FIG. 2C shows temporal change in the graph of FIG. 2B, and is a graph in which the magnitude of the index value Δrₖ is expressed by different shades. In the example shown in the drawing, the index value Δrₖ becomes large at the position indicated by the reference sign A, and it is considered that initial disconnection occurred at this point. Basically, when disconnection occurs, the change in the resistance value of the conductor (the index value Δrₖ) becomes large at an angle at which the effect of strain applied to the conductor before the disconnection is large (±90 degrees in the example shown in the drawing). Thereafter, as the strand disconnection progresses (i.e., the strand disconnection rate increases), the change in the resistance value (the index value Δrₖ) is expected to become large also at other angles.

Disconnection detection processing unit 23

The disconnection detection processing unit 23 performs disconnection detection processing to detect disconnection of strands constituting the conductor based on the analysis result (the analysis data 33) obtained in the analytical processing unit 22. The disconnection detection processing corresponds to the disconnection detection step of the invention. In the present embodiment, the disconnection detection processing unit 23 detects disconnection of strands constituting the conductor based on the index value Ark obtained by the analytical processing.

The disconnection detection processing unit 23 determines whether the index value Δrₖ at the predetermined angle αₖ is larger than a preset threshold value. By appropriately setting this threshold value, it is possible to detect the initial disconnection (to detect that strand disconnection has begun to occur) or to detect that a predetermined disconnection progress state has been reached. For example, when desired to detect that the disconnection progress state has reached a state two weeks before complete disconnection of all the plural strands constituting the conductor, the motion information data 31 and the resistance value data 32 from the brand new condition to complete disconnection of the conductor are acquired in advance and temporal change as shown in FIG. 2C is created. Then, using this data transition in FIG. 2C, the index value Δrₖ at the angle αₖ at the time two weeks back from the complete disconnection may be set as a threshold value for disconnection detection. In this way, by determining whether the index value Δrₖ at a predetermined angle αₖ is larger than the preset threshold value in the disconnection detection processing unit 23, it is possible to detect occurrence of strand disconnection or to detect whether the conductor has reached a predetermined disconnection progress state. The disconnection detection processing unit 23 may issue an alarm when the index value Δrₖ at the predetermined angle αₖ is larger than the preset threshold value. The disconnection detection processing unit 23 stores the result of disconnection detection (the determination result) as disconnection detection data 34 in the storage unit 3. Plural threshold values may be set in stages, so that what is the current disconnection progress state can be detected by comparing the index value Δrₖ with the plural threshold values.

However, it is not limited thereto, and the disconnection detection processing unit 23 may be configured to detect strand disconnection using machine learning based on the analysis data 33. In other words, the disconnection detection processing unit 23 may use a trained model created in advance and detect strand disconnection from the analysis result as a target subject to disconnection detection. As the training model, it is preferable to use a model trained using training data that includes the analysis result (the index value Δrₖ described above) when there is no strand disconnection. In more particular, for example, the presence or absence of disconnection may be detected by using anomaly detection with an autoencoder. In the case of performing anomaly detection with an autoencoder, the autoencoder repeatedly learns, in advance, the index value Δrₖ for each angle αₖ in the state with no disconnection. The autoencoder that has repeatedly learned the index value Δrₖ in a normal state outputs the index value Δrₖ with no anomaly as a predicted value even when the index value Δrₖ with some sort of anomaly is input. Therefore, when the input index value Δrₖ has some sort of anomaly, a deviation (an error) occurs between the input value and the predicted value. Thus, by determining whether the degree of this deviation is larger than a preset threshold value, it is possible to detect that strand disconnection has started to occur. Whether the conductor has reached a predetermined disconnection progress state can also be detected by appropriately adjusting the threshold value. In this regard, strand disconnection can be detected using various machine learning algorithms such as support vector machine, without limiting to anomaly detection with an autoencoder.

In the present embodiment, plural industrial robots 11a (and robot control devices 12) are connected to the disconnection detection device 1, and detection of disconnection of strands constituting the conductor in the cable 10 is performed in the plural industrial robots 11a. Therefore, it is possible to efficiently collect data for performing machine learning by efficiently collecting the motion information data 31 and the resistance value data 32, and it is thus possible to create the trained model by performing learning using a large amount of data. The accuracy of prediction by the trained model is thereby improved. The industrial robot 11a is provided per robot control device 12 in the example in FIG. 1, but plural industrial robots 11a may be controlled by a single robot control device 12. In addition, the disconnection detection device 1 may have a function as the robot control device 12.

Cable lifetime prediction processing unit 24

The cable lifetime prediction processing unit 24 performs cable lifetime prediction processing to predict the time to the conductor disconnection, i.e., the time until the cable 10 reaches the end of its life (hereinafter, referred to as the cable lifetime), based on the value of the index value Δrₖ. The cable lifetime prediction processing unit 24 preferably predicts the cable lifetime in consideration of the disconnection progress state detected by the disconnection detection processing unit 23 and the operating conditions of the moving part 11b. For example, by obtaining temporal change as shown in FIC. 2C in advance and referring to this temporal change, how much time will elapse before the cable lifetime is reached may be predicted from the time corresponding to the current index value Δrₖ. The prediction result in the cable lifetime prediction processing is stored as lifetime prediction data 35 in the storage unit 3. In this regard, the cable lifetime prediction processing unit 24 is not essential and can be omitted.

Disconnection detection method

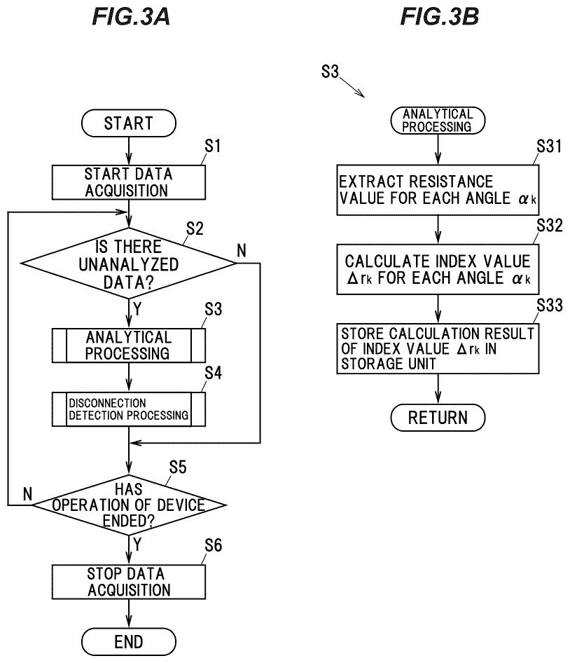

FIG. 3A is a flowchart showing a disconnection detection method in the present embodiment. The flow shown in FIG. 3A is started when the device 11 starts operating. As shown in FIGS. 3A and 3B, first, the data acquisition processing unit 21 starts acquiring the motion information data 31 and the resistance value data 32 from the resistance value detection unit 12b in Step S1. After that, in Step S2, the analytical processing unit 22 determines whether unanalyzed resistance value data 32 exists in the storage unit 3 (e.g., whether 30 minutes worth of unanalyzed data exists). Alternatively, in Step S2, whether a predetermined period of time has elapsed (e.g., whether 30 minutes have elapsed) since the last analysis may be determined.

After that, the analytical processing is performed in Step S3. In the analytical processing, as shown in FIG. 3B, the analytical processing unit 22 extracts the resistance value for each angle αₖ of the moving part 11b based on the motion information data 31 and the resistance value data 32 in Step S31, and calculates the index value Δrₖ for each angle αₖ using the above equations (1) to (3) in Step S32. After that, the analytical processing unit 22 stores the calculation result of the index value Δrₖ as the analysis data 33 in the storage unit 3 in Step S33, and the process then returns and proceeds to Step S4 in FIG. 3A.

In Step S4, the disconnection detection processing is performed. In the disconnection detection processing, the disconnection detection processing unit 23 detects whether disconnection has occurred in strands (whether strand disconnection has started to occur), based on the calculation result of the index value Δrₖ (the analysis data 33). In this regard, whether the conductor has reached a predetermined disconnection progress state can be detected by appropriately adjusting the threshold value. The detection result is stored as the disconnection detection data 34 in the storage unit 3. In addition, the detection result may be displayed on the display device 4, and an alert may be issued when disconnection is detected.

After that, in Step S5, it is determined whether the operation of the device 11 has ended. When the determination made in Step S5 is NO, the process returns to Step S2. When the determination made in Step S5 is YES, the data acquisition by the data acquisition processing unit 21 is finished in Step S6 and the process then ends. Although not shown in the drawing, the cable lifetime prediction processing may be performed after Step S6.

Other embodiments

In the embodiment described above, the case where disconnection detection is performed using the index value Δrₖ for each angle αₖ has been described. However, it is not limited thereto and other index values can also be used. Next, the embodiment using frequency analysis will be described.

In this embodiment, the analytical processing unit 22 performs frequency analysis on the motion information data 31 and the resistance value data 32 during a predetermined period of time. In more particular, a Fast Fourier Transform (FFT) is performed on each of the motion information data 31 and the resistance value data 32 during a predetermined period of time (e.g., 30 minutes). By performing a Fast Fourier transform on the motion information data 31 (in this example, data of changes in the angle a over time), an angle α(t) is converted into the following equation (4). In the equation (4), ωₙₐ is the angular frequency and α_{ωn} is the frequency component corresponding to the angular frequency ωₙₐ (n is an integer of not less than 1).

$$α ( t ) = {α}_{ω 1} {f}_{1 a} ( t ) + {α}_{ω 2} {f}_{2 a} ( t ) ++ + {α}_{ω 3} {f}_{3 a} ( t ) + … + {α}_{ω n} {f}_{na} ( t ) \qquad ( 4 )$$

Note: fₙₐ(t)=sinωₙₐt

Likewise, by performing a Fast Fourier transform (FFT) on the resistance value data 32, a resistance value r (t) is converted into the following equation (5). In the equation (5), ωₘᵣ is the angular frequency and r_{ωm} is the frequency component corresponding to the angular frequency ωₘᵣ (m is an integer of not less than 1).

$$r ( t ) = {r}_{ω 1} {f}_{1 r} ( t ) + {r}_{ω 2} {f}_{2 r} ( t ) + {r}_{ω 3} {f}_{3 r} ( t ) + … + {r}_{ω m} {f}_{mr} ( t ) \qquad ( 5 )$$

Note: fₘᵣ(t)=sinωₘᵣt

Then, the analytical processing unit 22 calculates an index value I=α_{ωn}×r_{ωm} by multiplying an arbitrary frequency component α_{ωn} of the motion information data 31 and an arbitrary frequency component r_{ωm} of the resistance value data 32, which are obtained by the frequency analyses. In this example, n×m index values I are obtained by multiplying the two frequency components α_{ωn} and r_{ωm} in all combinations. However, it is not limited thereto. Only combinations with which changes are likely to occur at the event of disconnection may be picked up and used as the index values I.

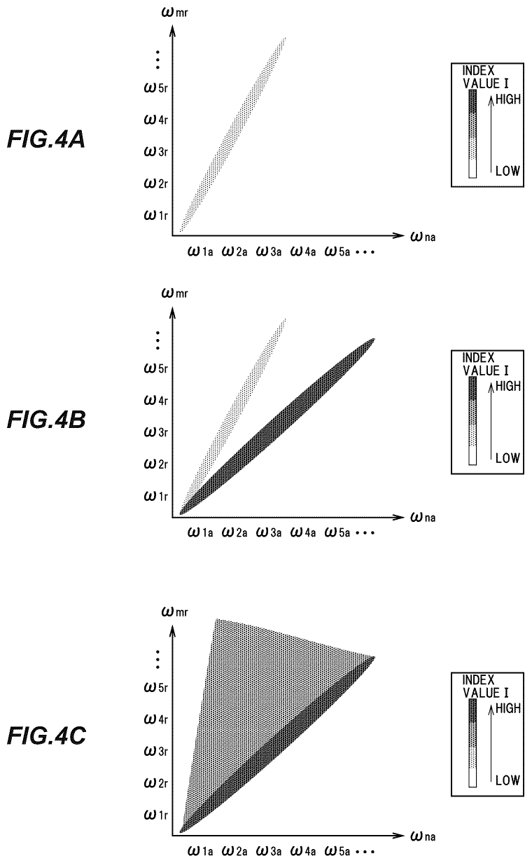

As shown in FIG. 4A, in the state in which the strands constituting the conductor are not disconnected, the index value I at which ωₙₐ:ωₘᵣ is a certain ratio (e.g., a ratio of integers) becomes large due to the effect of strain which is applied to the conductor by the motion of the moving part 11b. In particular, when the moving part 11b is operated in a manner causing the cable 10 to be repeatedly bend left and right, the strain on the conductor becomes large when the angle is the maximum at the left and right sides in one cycle of motion, hence, the resistance value becomes large twice in one cycle of motion. In such a case, the index value I for the combination of ωₙₐ:ωₘᵣ=1:2 becomes large even when the strands are not disconnected.

Furthermore, as shown in FIG. 4B, when disconnection of the strands constituting the conductor occurs, the index value I at which ωₙₐ:ωₘᵣ is a certain ratio becomes large (larger than the index value I under the effect of strain). For example, in the above-mentioned case where the cable 10 is repeatedly bend left and right, the distance between strands increases at the disconnection portion and this causes an increase in the index value I, hence, the index value I for the combination of ωₙₐ:ωₘᵣ1:1 becomes large. In this regard, the ratio ωₙₐ:ωₘᵣ for the index value I which becomes large at the event of disconnection varies depending on the type of motion of the moving part 11b (twisting, U-bending, etc.) and arrangement of the cable 10, etc. There is also a case where, e.g., the index value I which has become large due to strain becomes even larger when strand disconnection occurs. As the strand disconnection further progresses (i.e., as the number of disconnected strand increases), the index values I for various combinations are expected to become large, as shown in FIG. 4C. In the graphs shown in FIGS. 4A to 4C, different shades at the intersections of the two angular frequencies ωₙₐ and ωₘᵣ indicate the magnitude (intensity) of the index value I which is the result of multiplying the frequency component α_{ωn} of the angle corresponding to the angular frequency ωₙₐ on the horizontal axis by the frequency component r_{ωm} of the resistance value corresponding to the angular frequency ωₘᵣ on the vertical axis.

The disconnection detection processing unit 23 detects disconnection of the strands constituting the conductor based on the results of frequency analyses on both the motion information data 31 and the resistance value data 32 performed by the analytical processing unit 22. In this example, the disconnection detection processing unit 23 detects strand disconnection based on the index values I for all combinations (n×m combinations) obtained by calculation in the analytical processing unit 22. The disconnection detection processing unit 23 uses, e.g., a trained model created in advance and detects strand disconnection from the n×m index values I as a target subject to disconnection detection. Here, an autoencoder that has repeatedly learned the index value I when there is no disconnection in the conductor can be used as the trained model, and disconnection detection can be performed using anomaly detection with an autoencoder in the same manner as the embodiment describe above.

The n×m index values I are used here. However, the number of data is relatively large, which increases the computational load in some cases. Therefore, among them, the index values I for combinations largely affected by strand disconnection may be combined and used to reduce the number of data. As described above, strand disconnection has a large impact on the index value I at which the frequency ratio of angle to resistance (ωₙₐ:ωₘᵣ) is a certain ratio (e.g., an integer of not less than 1). Therefore, the detection may be performed in such a manner that the analytical processing unit 22 calculates an index value Ix using the following equation (6) by adding the product of frequency components whose frequency is x times the resistance value data 32 (where x is an integer of not less than 1), to the motion information data 31, and the disconnection detection processing unit 23 detects strand disconnection based on the index value Iₓ obtained by the calculation.

$$Ix = {\sum }_{{ω}_{mr} / {ω}_{na} = x} ( {α}_{ω n} \times {r}_{ω m} ) \qquad ( 6 )$$

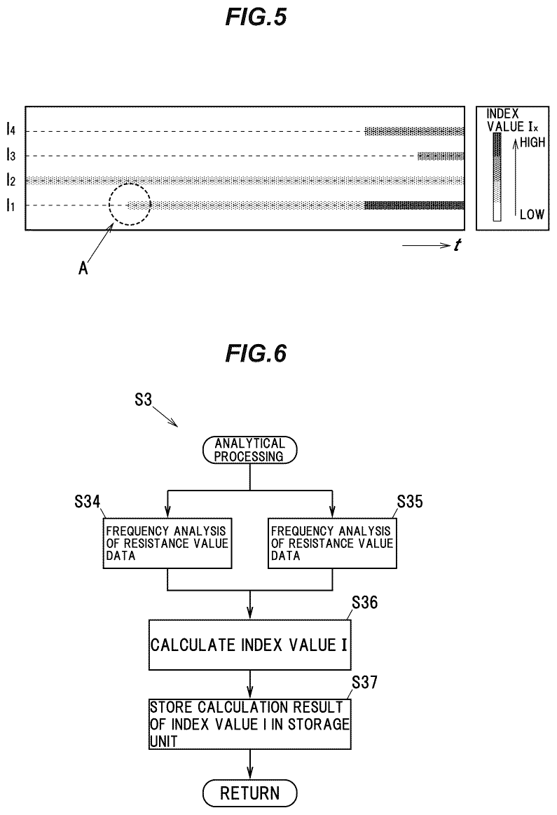

FIG. 5 is a diagram illustrating an example of changes in the index values Iₓ. In the example shown in the drawing, the index value I₂ is relatively large due to the effect of the strain applied to the conductor even in the state in which there is no strand disconnection. Then, the index value I₁ becomes large when the initial disconnection occurs (at the position indicated by the reference sign A). As time further passes and conductor disconnection progresses (the number of disconnected strand increases), the other index values I₃ and I₄ also become large. In this way, these index values Iₓ can be used to detect the conductor disconnection progress state.

FIG. 6 is a flowchart showing the analytical processing in another embodiment. As shown in FIG. 6, first, frequency analysis is performed on the resistance value data 32 in Step S34 and frequency analysis is also performed on the motion information data 31 in Step S35. After that, n×m index values I are calculated in Step S36, and the calculation results of the index values I are stored as the analysis data 33 in the storage unit 3 in Step S36.

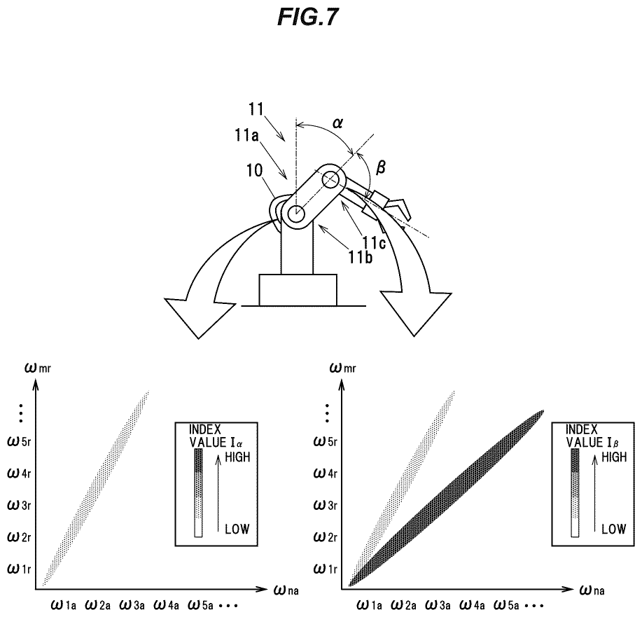

When the device 11 has plural moving parts, the same analysis can be performed for each moving part to detect disconnection. For example, assuming that the device 11 has two moving parts 11_{b} and 11_{c}, where the angle of one moving part 11_{b} is α, and the angle of the other moving part 11_{c} is β, as shown in FIG. 7. When a Fast Fourier Transform (FFT) is performed on each of data (the motion information data 31) of the angles α and β of the two moving parts 11b and 11c, the following equations (7) and (8) are obtained.

$$α ( t ) = {α}_{ω 1} {f}_{1 a} ( t ) + {α}_{ω 2} {f}_{2 a} ( t ) + {α}_{ω 3} {f}_{3 a} ( t ) + … + {α}_{ω n} {f}_{na} ( t ) \qquad ( 7 )$$

$$β ( t ) = {β}_{ω 1} {f}_{1 a} ( t ) + {β}_{ω 2} {f}_{2 a} ( t ) + {β}_{ω 3} {f}_{3 a} ( t ) + … + {β}_{ω n} {f}_{na} ( t ) \qquad ( 8 )$$

Note: fₙₐ(t)=sinωₙₐt

The analytical processing unit 22 calculates an index value I_{α}=α_{ωn}×r_{ωm} by multiplying the frequency component don of the angle a of the moving part 11b by the frequency component r_{ωm} of the resistance value r for all combinations. The analytical processing unit 22 also calculates an index value I_{β}=β_{ωn}×r_{ωm} by multiplying the frequency component β_{ωn} of the angle β of the moving part 11c by the frequency component r_{ωm} of the resistance value r for all combinations.

The disconnection state of the conductor in the moving part 11b operating at the angle a appears in the frequency component r_{ωm} of the resistance value r related to the frequency component α_{ωn} of the angle α. Then, the disconnection state of the conductor in the moving part 11c operating at the angle β appears in the frequency component r_{ωn} of the resistance value r related to the frequency component β_{ωn} of the angle β. Therefore, by using the index value I_{α}calculated by multiplying the frequency component r_{ωm} by the frequency component α_{ωn} (i.e., the index value I_{α} emphasizing the frequency component r_{ωm} related to the frequency component α_{ωn}), it is possible to detect strand disconnection or the conductor disconnection progress state in the moving part 11b operating at the angle α. Likewise, by using the index value I_{β} calculated by multiplying the frequency component r_{ωn} by the frequency component β_{ωn} (i.e., the index value I_{β} emphasizing the frequency component r_{ωm} related to the frequency component β_{ωn}), it is possible to detect strand disconnection or the conductor disconnection progress state in the moving part 11c operating at the angle β. In this way, in the case of having plural moving parts 11b and 11c, by obtaining the index values I_{α} and I_{β} emphasizing the frequency components r_{ωm} of the resistance values r related to the respective motions of the moving parts 11b and 11c, strand disconnection or the conductor disconnection progress state can be detected for each of the moving parts 11b and 11c.

Functions and Effects of the embodiment

As described above, the disconnection detection method in the present embodiment includes a data acquisition step of acquiring the motion information data 31, which is data showing changes over time in information about the motion of the device 11, and the resistance value data 32, which is data of the resistance value of the conductor that changes in time series due to the motion of the device 11, an analysis step of analyzing the resistance value data 32 based on the motion information data 31 acquired in the data acquisition step and obtaining an index value to detect strand disconnection, and a disconnection detection step of detecting strand disconnection based on the index value obtained in the analysis step.

The resistance value which changes in accordance with the motion can be detected by performing analysis on the resistance value data 32 based on the motion information data 31, and based on this detection result, disconnection detection can be performed even in the state in which the device 11 with the cable 10 mounted thereon is in actual operation. For the device 11 used in, e.g., a factory, etc., such as the industrial robot 11a, operating time is far longer than non-operating time during which maintenance, etc. can be performed. Therefore, by making it possible to use the data collected during operation, more data can be collected and the accuracy of disconnection detection using machine learning can be improved.

Modified Example

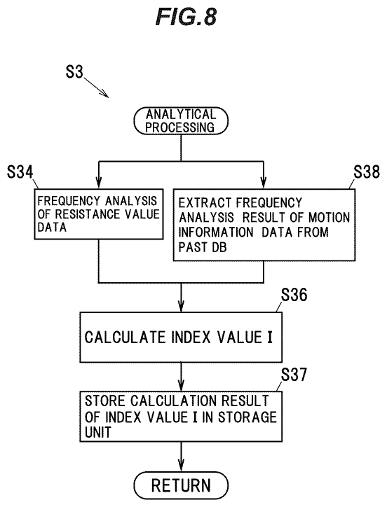

In the embodiment described above, disconnection detection is performed using the motion information data 31 and the resistance value data 32. However, when it is not possible to acquire the motion information data 31 for some reason, disconnection detection can be performed by generating (or predicting) the motion information data 31 from the resistance value data 32. For example, the configuration may be such that the frequency analysis result of the resistance value data and frequency analysis result of motion information data are associated with each other and stored as a database in advance, data closest to the frequency analysis result of the measured resistance value data is extracted from the database, and the index value I is calculated using the frequency analysis result of the motion information data included in the extracted data. In this case, in place of Step S35 in FIG. 6, processing to extract the frequency analysis result of the motion information data from the past database (DB) may be performed in Step S38, as shown in FIG. 8.

When there is no disconnection in the conductor, the index value I at which ωₙₐ:ωₘᵣ is a certain ratio becomes large due to the effect of the strain which is applied to the conductor by the motion of the moving part 11b, and this tendency continues to some extent even as the disconnection progresses. Therefore, if the ωₙₐ:ωₘᵣ ratio where the index value I becomes large due to the effect of strain is confirmed in advance, the result of the frequency analysis of the motion information data 31 can be generated using the frequency analysis result of the of the resistance value data 32. That is, it is possible to perform disconnection detection without acquiring the motion information data 31.

In more particular, if the frequency component α_{ωn} corresponding to the angular frequency ωₙₐ is unknown when calculating the index value I, the frequency component Ton corresponding to the angular frequency ωₘᵣ can be used as a substitute for α_{ωn} to calculate the index value I as long as the ωₙₐ:ωₘᵣ ratio relationship such as ωₙₐ=ωₘᵣ/2 as shown in FIG. 4A is confirmed in advance. For example, when applying a bending motion causing the resistance value to become large twice in one cycle of motion, the index value I for the combination of ωₙₐ:ωₘᵣ=1:2 becomes large. In other words, the index value I for the combination with ωₙₐ=ωₘᵣ/2 becomes large. Therefore, by using r_{ωn}/2 instead of don, the index value I can be calculated by the following equation (9).

$$I = {r}_{ω n} / 2 \times {r}_{ω m} \qquad ( 9 )$$

In this regard, however, n×m index values I may be obtained by multiplying two frequency components r_{ωn} and r_{ωm} in all combinations, or only combinations with which changes are likely to occur at the event of disconnection may be picked up and used as the index values I.

Summary of the embodiments

Next, the technical concepts that can be grasped from the above embodiments will be described with the help of the codes, etc. in the embodiments. However, each sign, etc. in the following description is not limited to the members, etc. specifically shown in the embodiment for the constituent elements in the scope of claims.

According to the first feature, a disconnection detection method for detecting disconnection of a plurality of strands constituting a conductor of a cable 10 wired in a device 11 that is caused by motion of the device 11, the method comprising: a data acquisition step of acquiring motion information data 31, which is data showing changes over time in information about motion of the device 11, and resistance value data 32, which is data of a resistance value of the conductor that changes in time series due to the motion of the device 11; an analysis step of analyzing the resistance value data 32 based on the motion information data 31 acquired in the data acquisition step and obtaining an index value to detect strand disconnection; and a disconnection detection step of detecting the strand disconnection based on the index value obtained in the analysis step.

According to the second feature, in the disconnection detection method as described in the first feature, in the analysis step, for each state of motion, an average value rₖ of the resistance value over a predetermined period of time when the motion is in that state is calculated and the index value is obtained by normalizing the average value, and in the disconnection detection step, the strand disconnection is detected based on the index value obtained in the analysis step.

According to the third feature, in the disconnection detection method as described in the first or second feature, in the analysis step, frequency analyses are performed on the motion information data 31 and the resistance value data 32 during a predetermined period of time and the index value is obtained based on results of the frequency analyses, and in the disconnection detection step, the strand disconnection is detected based on the index value obtained in the analysis step.

According to the fourth feature, in the disconnection detection method as described in the third feature, in the analysis step, the index value I is calculated by multiplying an arbitrary frequency component of the motion information data 31 and an arbitrary frequency component of the resistance value data 32, which are results of the frequency analyses, and in the disconnection detection step, the strand disconnection is detected based on the index value obtained in the analysis step.

According to the fifth feature, in the disconnection detection method as described in the third feature, in the analysis step, based on the results of the frequency analyses, the index value Iₓ is calculated by adding a product of frequency components whose frequency is x times the resistance value data 32 (where x is an integer or not less than 1), to the motion information data 31, and in the disconnection detection step, the strand disconnection is detected based on the index value obtained in the analysis step.

According to the sixth feature, in the disconnection detection method as described in the any one of the first to fifth features, in the disconnection detection step, by using a trained model created by performing learning in advance with use of training data including the index value when there is no strand disconnection, the strand disconnection is detected based on the index value as the target subject to disconnection detection.

According to the seventh feature, a disconnection detection device 1 detects disconnection of a plurality of strands constituting a conductor of a cable 10 wired in a device 11 that is caused by motion of the device 11, the disconnection detection device 1 comprising: a data acquisition processing unit 21 that acquires motion information data 31, which is data showing changes over time in information about motion of the device 11, and resistance value data 32, which is data of a resistance value of the conductor that changes in time series due to the motion of the device 11; an analytical processing unit 22 that analyzes the resistance value data 32 based on the motion information data 31 acquired by the data acquisition processing unit 21 and obtains an index value to detect strand disconnection; and a disconnection detection processing unit 23 that detects the strand disconnection based on the index value obtained by the analytical processing unit 22.

According to the eighth feature, a disconnection detection device 1 detects disconnection of a plurality of strands constituting a conductor of a cable 10 wired in a device 11 that is caused by motion of the device 11, the disconnection detection device 1 comprising: a data acquisition processing unit 21 that acquires resistance value data 32 which is data of a resistance value of the conductor that changes in time series due to the motion of the device 11; an analytical processing unit 22 that generates motion information data 31, which is data showing changes over time in information about motion of the device, from the resistance value data 32, analyzes the resistance value data 32 based on the motion information data 31 and obtains an index value to detect strand disconnection; and a disconnection detection processing unit 23 that detects the strand disconnection based on the index value obtained by the analytical processing unit 22.

The above description of the embodiments of the invention does not limit the invention as claimed above. It should also be noted that not all of the combinations of features described in the embodiments are essential to the means for solving the problems of the invention. In addition, the invention can be implemented with appropriate modifications to the extent that it does not depart from the gist of the invention.

1. A disconnection detection method for detecting disconnection of a plurality of strands constituting a conductor of a cable wired in a device that is caused by motion of the device, the method comprising:
a data acquisition step of acquiring motion information data, which is data showing changes over time in information about motion of the device, and resistance value data, which is data of a resistance value of the conductor that changes in time series due to the motion of the device;
an analysis step of analyzing the resistance value data based on the motion information data acquired in the data acquisition step and obtaining an index value to detect strand disconnection; and
a disconnection detection step of detecting the strand disconnection based on the index value obtained in the analysis step.

2. The method according to claim 1, wherein in the analysis step, for each state of motion, an average value of the resistance value over a predetermined period of time when the motion is in that state is calculated and the index value is obtained by normalizing the average value, and wherein in the disconnection detection step, the strand disconnection is detected based on the index value obtained in the analysis step.

3. The method according to claim 1, wherein in the analysis step, frequency analyses are performed on the motion information data and the resistance value data during a predetermined period of time and the index value is obtained based on results of the frequency analyses, and wherein in the disconnection detection step, the strand disconnection is detected based on the index value obtained in the analysis step.

4. The method according to claim 3, wherein in the analysis step, the index value is calculated by multiplying an arbitrary frequency component of the motion information data and an arbitrary frequency component of the resistance value data, which are results of the frequency analyses, and wherein in the disconnection detection step, the strand disconnection is detected based on the index value obtained in the analysis step.

5. The method according to claim 3, wherein in the analysis step, based on the results of the frequency analyses, the index value is calculated by adding a product of frequency components whose frequency is x times the resistance value data (where x is an integer or not less than 1), to the motion information data, and wherein in the disconnection detection step, the strand disconnection is detected based on the index value obtained in the analysis step.

6. The method according to claim 1, wherein in the disconnection detection step, by using a trained model created by performing learning in advance with use of training data including the index value when there is no strand disconnection, the strand disconnection is detected based on the index value as a target subject to disconnection detection.

7. A disconnection detection device that detects disconnection of a plurality of strands constituting a conductor of a cable wired in a device that is caused by motion of the device, the disconnection detection device comprising:
a data acquisition processing unit that acquires motion information data, which is data showing changes over time in information about motion of the device, and resistance value data, which is data of a resistance value of the conductor that changes in time series due to the motion of the device;
an analytical processing unit that analyzes the resistance value data based on the motion information data acquired by the data acquisition processing unit and obtains an index value to detect strand disconnection; and
a disconnection detection processing unit that detects the strand disconnection based on the index value obtained by the analytical processing unit.

8. A disconnection detection device that detects disconnection of a plurality of strands constituting a conductor of a cable wired in a device that is caused by motion of the device, the disconnection detection device comprising:
a data acquisition processing unit that acquires resistance value data which is data of a resistance value of the conductor that changes in time series due to the motion of the device;
an analytical processing unit that generates motion information data, which is data showing changes over time in information about motion of the device, from the resistance value data, analyzes the resistance value data based on the motion information data and obtains an index value to detect strand disconnection; and
a disconnection detection processing unit that detects the strand disconnection based on the index value obtained by the analytical processing unit.
